(19) United States
(12) Patent Application Publication
(10) Pub. No.: US 2025/0318106 A1
(43) Pub. Date: Oct. 9, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Wai-Kit LEE, Hsinchu (TW); Chih-Yu CHANG, Hsinchu (TW); Chien-Hao HUANG, Hsinchu (TW); Katherine H. CHIANG, Hsinchu (TW); Yun-Feng Kao, Hsinchu (TW); Chen-Jun WU, Hsinchu (TW); Yen-Chung HO, Hsinchu (TW); Yong-Jie Wu, Hsinchu (TW)

(73) Assignee: Taiwan Semiconductor Manufacturing Company, Ltd., Hsinchu (TW)

(21) Appl. No.: 18/626,435

(22) Filed: Apr. 4, 2024

(51) Int. Cl. H10B 12/00

(52) U.S. Cl. CPC H10B 12/33; H10B 12/05

(57) ABSTRACT

A semiconductor device includes a BEOL structure, a transistor and a capacitor. The transistor is formed on the BEOL structure and includes an active channel and a metal gate. The capacitor is formed within the BEOL structure. The active channel has a lateral surface and extends a thickness direction of the semiconductor device. The metal gate is formed adjacent to the lateral surface of the active channel. In an embodiment, the active channel is a vertical active channel.

### BACKGROUND

To have high density DRAM (Dynamic Random Access Memory), one general approach is to scale the geometry of the access transistor. However, reducing the channel length usually results in a more serious short channel effect, e.g. higher subthreshold swing and higher channel leakage.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrate a schematic diagram of a semiconductor device according to an embodiment of the present disclosure;

FIG. 1B illustrates a schematic diagram of a cross-sectional view of the semiconductor device in FIG. 1A along a direction 1B-1B′;

FIG. 1C illustrates a schematic diagram of a cross-sectional view of the semiconductor device in FIG. 1A along a direction 1C-1C′;

FIG. 2A illustrates a schematic diagram of a semiconductor device according to another embodiment;

FIG. 2B illustrates a schematic diagram of a cross-sectional view of the semiconductor device in FIG. 2A along a direction 2B-2B′;

FIG. 3 illustrates a schematic diagram of a cross-sectional view of a semiconductor device according to another embodiment;

FIG. 4 illustrates a schematic diagram of a cross-sectional view of a semiconductor device according to another embodiment;

FIG. 5 illustrates a schematic diagram of a cross-sectional view of a semiconductor device according to another embodiment;

FIG. 6 illustrates a schematic diagram of a cross-sectional view of a semiconductor device according to another embodiment;

FIG. 7 illustrates a schematic diagram of a cross-sectional view of a semiconductor device according to another embodiment;

FIG. 8 illustrates a schematic diagram of a cross-sectional view of a semiconductor device according to another embodiment;

FIGS. 9A to 9O illustrate schematic diagrams of manufacturing processes of the semiconductor device in FIG. 1A;

FIGS. 10A to 10J illustrate schematic diagrams of manufacturing processes of the semiconductor device in FIG. 7; and

FIGS. 11A to 11I illustrate schematic diagrams of manufacturing processes of the semiconductor device in FIG. 8.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

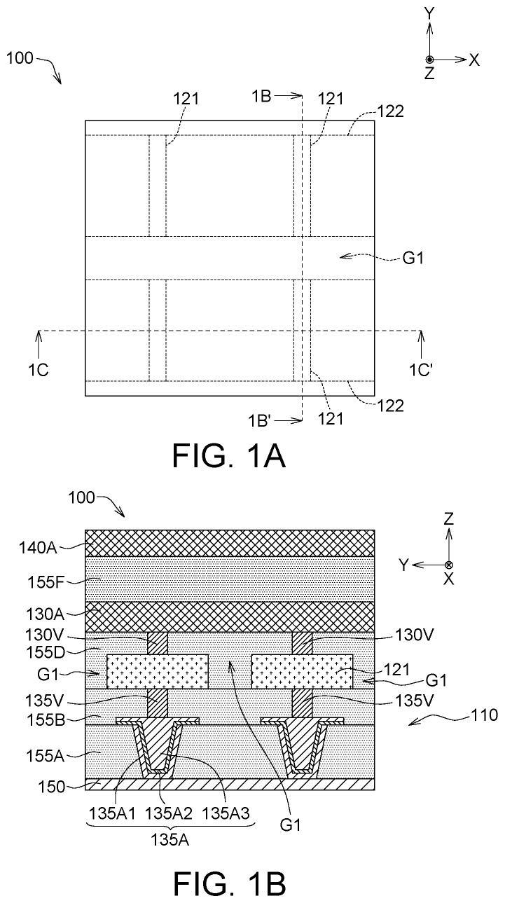

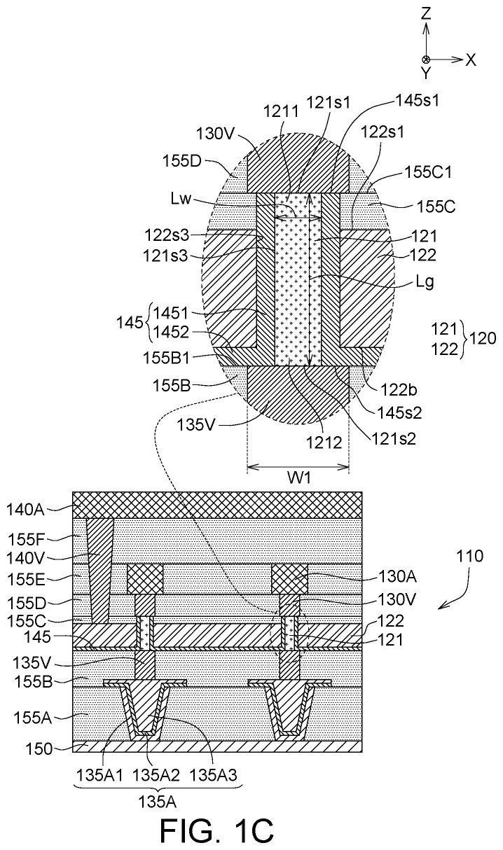

As illustrated in FIGS. 1A to 1C, FIG. 1A illustrate a schematic diagram of a top view of a semiconductor device 100 according to an embodiment of the present disclosure, FIG. 1B illustrates a schematic diagram of a cross-sectional view of the semiconductor device 100 in FIG. 1A along a direction 1B-1B′, and FIG. 1C illustrates a schematic diagram of a cross-sectional view of the semiconductor device 100 in FIG. 1A along a direction 1C-1C′. The semiconductor device 100 may apply to memory, for example, DRAM.

As illustrated in FIGS. 1A to IC, the semiconductor device 100 includes a Back End of Line (BEOL) structure 110, at least one transistor 120, at least one bit line 130A, at least one bit line via 130V, at least one capacitor 135A, at least one capacitor via 135V, at least one word line 140A, at least one word line via 140V, a gate dielectric layer 145, a conductive layer 150 and at least one insulation layer (for example, including a first insulation layer 155A, a second insulation layer 155B, a third insulation layer 155C, a fourth insulation layer 155D, a fifth insulation layer 155E, a sixth insulation layer 155F, etc.). The bit line 130A, the bit line via 130V, the capacitor 135A, the capacitor via 135V, the word line 140A, the word line via 140V, the gate dielectric layer 145, the conductive layer 150 and the insulation layer are formed on/within the BEOL structure 110.

As illustrated in FIGS. 1A to IC, the transistor 120 is, for example, a Thin-Film Transistor (TFT). The transistor 120 is formed in or on the BEOL structure 110 and includes an active channel 121 and a metal gate 122. The active channel 121 has a first end surface 121s1. The metal gate 122 has a first conductive surface 122s1. The first end surface 121s1 of the active channel 121 protrudes relative to the first conductive surface 122s1 of the metal gate 122.

As illustrated in FIG. 1C, the gate dielectric layer 145 has a first end surface 145s1 and a second end surface 145s2 opposite to the first end surface 145s1. The first end surface 145s1 of the gate dielectric layer 145, the first end surface 121s1 of the active channel 121 and the first conductive surface 122s1 of the metal gate 122 are substantially aligned (for example, flushed) with each other or substantially coplanar, for example. In addition, the active channel 121 further has a second end surface 121s2 opposite to the first end surface 121s1, wherein the second end surface 121s2 and the second end surface 145s2 are substantially aligned (for example, flushed) with each other or substantially coplanar, for example.

As illustrated in FIGS. 1B and 1C, the transistor 120 may further include a drain and a source. Furthermore, the active channel 121 includes a first end 1211 and a second end 1212. In an embodiment, the first end 1211 of the active channel 121 may serve as one of the drain and the source of the transistor 120, while the second end 1212 of the active channel 121 may serve as another of the drain and the source of the transistor 120. In another embodiment, the bit line via 130V may serve as one of the drain and the source of the transistor 120, while the capacitor via 135V may serve as another of the drain and the source of the transistor 120. In addition, the third insulation layer 155C is disposed between the bit line via 130V and the active channel 121 and isolates the bit line via 130V from the active channel 1213. As a result, the bit line via 130V and the active channel 121 may be electrically isolated from each other by the third insulation layer 155C.

As illustrated in FIGS. 1B and IC, the active channel 121 extends in the thickness direction Z to provide a vertical channel parallel to the thickness direction Z, and it may help to reduce cell area and results in high density DRAM. The active channel 121 has a channel length Lg in the thickness direction Z and a channel thickness Lw in a direction X, wherein the channel length Lg may be greater than the channel thickness Lw, for example. In an embodiment, the channel length Lg ranges between, for example, 3 nanometers (nm) and 30 micrometers (μm), and the channel thickness Lw ranges between, for example, 3 nm and 50 nm. In addition, the metal gate 122 and the bit line via 130V overlap in an extension direction (for example, the direction X) perpendicular to the thickness direction Z of the semiconductor device 100. Furthermore, the active channel 121 has a lateral surface 121s3, and the metal gate 122 has a lateral surface 122s3, wherein a normal direction (for example, −X direction) of the lateral surface 121s3 and a normal direction (for example, +X direction) of the lateral surface 122s3 are in two opposite directions respectively, and the lateral surface 121s3 and the lateral surface 122s3 face two opposite surfaces of the gate dielectric layer 145. In addition, the metal gate 122 is disposed adjacent to the lateral surface 121s3 of the active channel 121. Furthermore, the lateral surface 121s3 of the active channel 121 may be spaced from the metal gate 122 by the gate dielectric layer 145.

As illustrated in FIG. 1C, the capacitor via 135V has a width (or thickness) W1 in the X direction, and the channel thickness Lw is less than the width (or thickness) W1 of the capacitor via 135V.

In an embodiment, the active channel 121 may be a single-layered structure or a multi-layered structure. To have lower drain/source resistance, the active channel 121 may be the multi-layered structure. Furthermore, the channel material concentration/composition at a top layer, a central layer and a bottom layer of the active channel 121 may be different such that it may lower SD contact and/or the drain/source resistance. To lower SD contact and/or the drain/source resistance, the material composition of the capacitor via 135V and/or the bit line via 130V which contacts the active channel 121 may be altered to lower SD contact and/or the drain/source resistance.

In some embodiments, the active channel 121 may be formed of one or more of InZnO (IZO), indium tin oxide (ITO), In2O3, Ga2O3, InGaZnO, ZnO, Al2O5Zn2 aluminum doped ZnO (AZO), IWO, TiOx. Or semiconductor materials comprising other III-V materials, combinations (e.g. alloys or stacked layers) of semiconductor materials.

In some embodiments, the metal gate 122 may be formed of a work function metal. The work function metal may be an N-type or P-type work function layer. Exemplary P-type work function metals include TiN, TaN, Ru, Mo, Al, WN, ZrSi2, MoSi2, TaSi2, NiSi2, WN, other suitable P-type work function materials, or combinations thereof. Exemplary N-type work function metals include Ti, Ag, TaAl, TaAlC, TiAlN, TaC, TaCN, TaSiN, Mn, Zr, other suitable N-type work function materials, or combinations thereof. The work function layer may contain multiple layers. The work function metal may be formed by a process such as ALD, CVD, PVD, remote plasma CVD (RPCVD), plasma enhanced CVD (PECVD), metal-organic CVD (MOCVD), sputtering, electroplating, other suitable processes, or the like. Formed by suitable processes such as combination.

As illustrated in FIGS. 1B and IC, the bit line via 130V, the active channel 121 and the bit line via 130V are stacked in a thickness direction Z of the semiconductor device 100. The bit line via 130V is connected with the first end surface 121s1 of the active channel 121, and the capacitor via 135V is connected with the second end surface 122s2 of the metal gate 122. Furthermore, the bit line via 130V connects the bit line 130A with the first end surface 121s1 of the active channel 121, and the capacitor via 135V connects the capacitor 135A with the second end surface 121s2 of the active channel 121.

In an embodiment, the bit line via 130V and/or the capacitor via 135V may be formed of a conductive material including metal, for example. The bit line 130A may be formed of a conductive material including metal, for example.

As illustrated in FIGS. 1B and 1C, in the present embodiment, the capacitors 135A are located below the transistor 120. The capacitor 135A includes a first electrode 135A1, a capacitor dielectric layer 135A2 and a second electrode 135A3, wherein the capacitor dielectric layer 135A2 is formed between the first electrode 135A1 and the second electrode 135A3. In the present embodiment, each second electrode 135A3 is connected with the corresponding capacitor via 135V. In an embodiment, at least two of the capacitors 135A may be directly or indirectly electrically connected with each other. In addition, the first electrode 135A1 and the second electrode 135A3 may be formed of a conductive material including metal, for example. The capacitor dielectric layer 135A2 may be formed of a high-k (HK) material, for example.

As illustrated in FIGS. 1B and 1C, the capacitor via 135V is formed on/above the capacitor 135A. The capacitor via 135V may be formed of a material including metal, for example.

As illustrated in FIG. 1C, the word line 140A is formed on the sixth insulation layer 155F. The word line via 140V connects the word line 140A with the metal gate 122 through the sixth insulation layer 155F, the fifth insulation layer 155E, the fourth insulation layer 155D and the third insulation layer 155C. In an embodiment, the word line via 140V may be formed of a conductive material including metal, for example.

As illustrated in FIG. 1C, the gate dielectric layer 145 is formed between the active channel 121 and the metal gate 122, and the metal gate 122 and the second insulation layer 155B. In an embodiment, the gate dielectric layer 145 includes a first portion 1451 and a second portion 1452, wherein the first portion 1451 is formed adjacent to the lateral surface 121s3 and formed between the lateral surface 121s3 of the active channel 121 and the lateral surface 122s3 of the metal gate 122. The second portion 1452 is formed between an end surface (for example, a lower surface) 122b of the metal gate 122 and an end surface (for example, an upper surface) 155B1 of the second insulation layer 155B. In an embodiment, the gate dielectric layer 145 may be formed of a high-k (HK) material, for example.

The high-k material may be formed of a material including: (i) a high-k dielectric material, such as hafnium oxide (HfO₂), titanium oxide (TiO₂), hafnium zirconium oxide (HfZrO), tantalum oxide (Ta₂O₃), hafnium silicate (HfSiO₄), zirconium oxide (ZrO₂), and zirconium silicate (ZrSiO₂), and (ii) a high-k dielectric material having oxides of lithium (Li), beryllium (Be), magnesium (Mg), calcium (Ca), strontium (Sr), scandium (Sc), yttrium (Y), zirconium (Zr), aluminum (A1), lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), (iii) other suitable high-k dielectric materials, or (iv) a combination thereof. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9).

As illustrated in FIGS. 1B and 1C, the first insulation layer 155A is formed on the conductive layer 150, wherein at least one portion of the capacitor 135A is formed within the first insulation layer 155A. The second insulation layer 155B is formed on/above the first insulation layer 155A and has at least one hole exposing the capacitor 135A, wherein the capacitor via 135V is formed within the hole to be connected with the capacitor 135A. The third insulation layer 155C is formed on/above the metal gate 122 for isolating the metal gate 122 form the bit line via 130V. The fourth insulation layer 155D covers the active channels 121. The fourth insulation layer 155D is formed within a gap G1 between the adjacent two active channels 121 and cover an upper surface of the active channels 121. The fourth insulation layer 155 has at least one hole exposing the active channels 121, wherein the bit line via 130V is formed within the hole to be connected with the active channels 121. The fifth insulation layer 155E is formed on/above the fourth insulation layer 155D and has at least one hole exposing the bit line via 130V, wherein the bit line 130A is formed within the hole to connected with bit line via 130V. The sixth insulation layer 155F is formed on/above the fifth insulation layer 155E. In an embodiment, the first insulation layer 155A, the second insulation layer 155B, the third insulation layer 155C, the fourth insulation layer 155D, the fifth insulation layer 155E and the sixth insulation layer 155F may be formed of an insulation material including, for example, oxide.

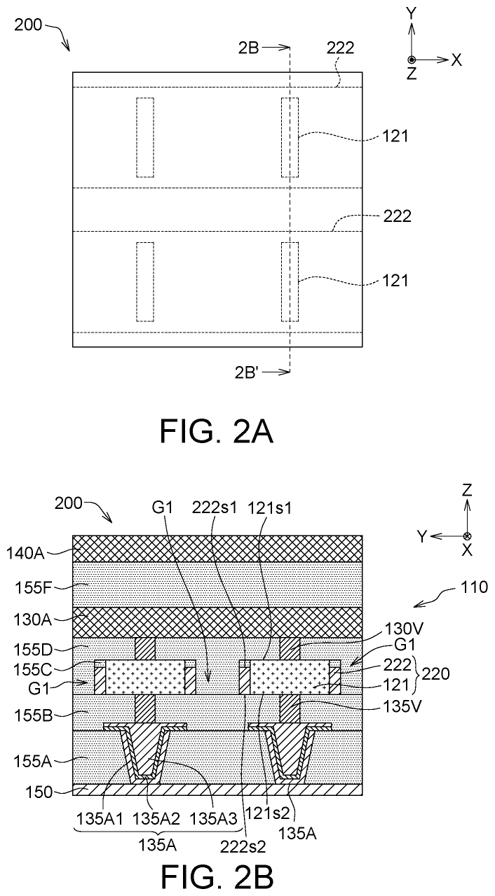

As illustrated in FIGS. 2A, FIG. 2A illustrates a schematic diagram of a top view of a semiconductor device 200 according to another embodiment, and FIG. 2B illustrates a schematic diagram of a cross-sectional view of the semiconductor device 200 in FIG. 2A along a direction 2B-2B′.

As illustrated in FIGS. 2A and 2B, the semiconductor device 200 includes the BEOL structure 110, at least one transistor 220, at least one bit line 130A, at least one bit line via 130V, at least one capacitor 135A, at least one capacitor via 135V, at least one word line 140A, at least one word line via 140V, the gate dielectric layer 145, the conductive layer 150 and at least one insulation layer (for example, including the first insulation layer 155A, a second insulation layer 155B, the third insulation layer 155C, the fourth insulation layer 155D, a the fifth insulation layer 155E, the sixth insulation layer 155F, etc.). The bit line 130A, the bit line via 130V, the capacitor 135A, the capacitor via 135V, the word line 140A, the word line via 140V, the gate dielectric layer 145, the conductive layer 150 and the insulation layer are formed on/within the BEOL structure 110.

As illustrated in FIG. 2B, the transistor 220 is formed on the BEOL structure 110 and includes the active channel 121 and a metal gate 222. The active channel 121 has the first end surface 121s1. The metal gate 222 has a first conductive surface 222s1. The first end surface 121s1 of the active channel 121 protrudes relative to the first conductive surface 222s1 of the metal gate 222. In addition, the metal gate 222 further has a second conductive surface 222s2 opposite to the first conductive surface 222s1, and the active channel 121 has a second end surface 121s2 opposite to the first end surface 121s1, wherein the second conductive surface 222s2 and the second end surface 121s2 are flushed with each other.

As illustrated in FIGS. 2A and 2B, the semiconductor device 200 includes the features the same as or similar to that of the semiconductor device 100, and at least one difference is that the metal gate 222 of the transistor 220 surrounds/encloses the active channel 121, which form a GAA (Gate All Around) structure.

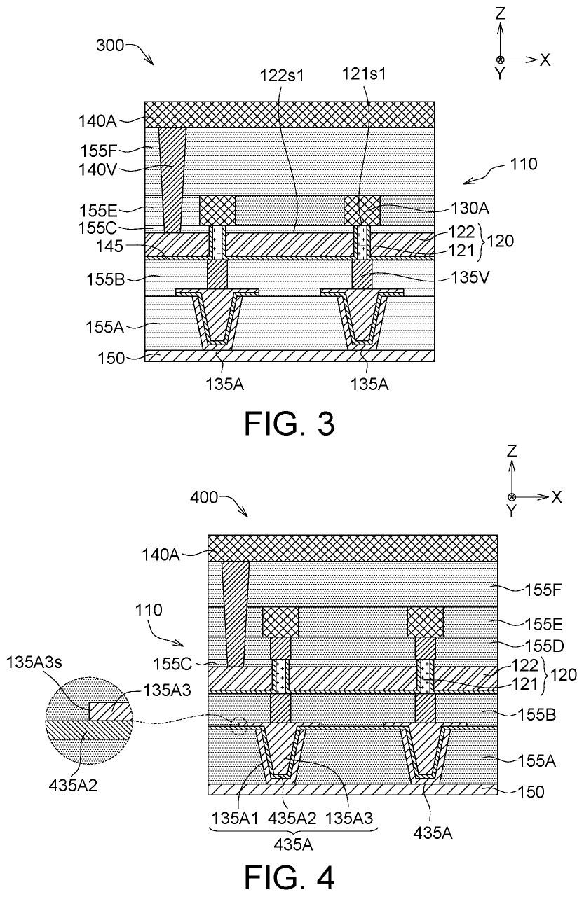

As illustrated in FIG. 3, FIG. 3 illustrates a schematic diagram of a cross-sectional view of a semiconductor device 300 according to another embodiment. The semiconductor device 300 includes the BEOL structure 110, at least one transistor 120, at least one bit line 130A, at least one capacitor 135A, at least one capacitor via 135V, at least one word line 140A, at least one word line via 140V, the gate dielectric layer 145, the conductive layer 150 and at least one insulation layer (for example, including the first insulation layer 155A, the second insulation layer 155B, the third insulation layer 155C, the fifth insulation layer 155E, the sixth insulation layer 155F, etc.). The bit line 130A, the capacitor 135A, the capacitor via 135V, the word line 140A, the word line via 140V, the gate dielectric layer 145, the conductive layer 150 and the insulation layer are formed on/within the BEOL structure 110.

As illustrated in FIG. 3, the transistor 120 is formed on the BEOL structure 110 and includes the active channel 121 and the metal gate 122. The active channel 121 has the first end surface 121s1. The metal gate 122 has the first conductive surface 122s1. The first end surface 121s1 of the active channel 121 protrudes relative to the first conductive surface 122s1 of the metal gate 122.

The semiconductor device 300 includes the features the same as or similar to that of the semiconductor device 100, and at least one difference is that the semiconductor device 300 may omit the bit line via 130V. Furthermore, in the present embodiment, as illustrated in FIG. 3, the bit line 130A may be connected with the active channel 121 without the bit line via 130V. For example, the bit line 130A may be directly connected with the active channel 121.

In another embodiment, the semiconductor device 300 also may omit the capacitor via 135V. In other embodiment, the semiconductor device 300 may omit at least one of the bit line via 130V and the capacitor via 135V.

As illustrated in FIG. 4, FIG. 4 illustrates a schematic diagram of a cross-sectional view of a semiconductor device 400 according to another embodiment. The semiconductor device 400 includes the BEOL structure 110, at least one transistor 120, at least one bit line 130A, at least one bit line via 130V, at least one capacitor 435A, at least one capacitor via 135V, at least one word line 140A, at least one word line via 140V, the gate dielectric layer 145, the conductive layer 150 and at least one insulation layer (for example, including the first insulation layer 155A, the second insulation layer 155B, a third insulation layer 155C, the fourth insulation layer 155D, the fifth insulation layer 155E, the sixth insulation layer 155F, etc.). The bit line 130A, the bit line via 130V, the capacitor 435A, the capacitor via 135V, the word line 140A, the word line via 140V, the gate dielectric layer 145, the conductive layer 150 and the insulation layer are formed on/within the BEOL structure 110.

The semiconductor device 400 includes the features the same as or similar to that of the semiconductor device 100, and at least one difference is that the capacitor 435A of the semiconductor device 400 and the capacitor 435A of the semiconductor device 100 are different in structure. Furthermore, in the present embodiment, as illustrated in FIG. 4, the capacitor 435A includes the first electrode 135A1, a capacitor dielectric layer 435A2 and the second electrode 135A3, wherein the capacitor dielectric layer 435A2 is formed between the first electrode 135A1 and the second electrode 135A3. The capacitor dielectric layer 435A2 may extend beyond a lateral surface 135A3s of the second electrode 135A3.

In addition, the first electrode 135A1 and the second electrode 135A3 may be formed of a conductive material including metal, for example. The capacitor dielectric layer 435A2 may be formed of a high-k material, for example.

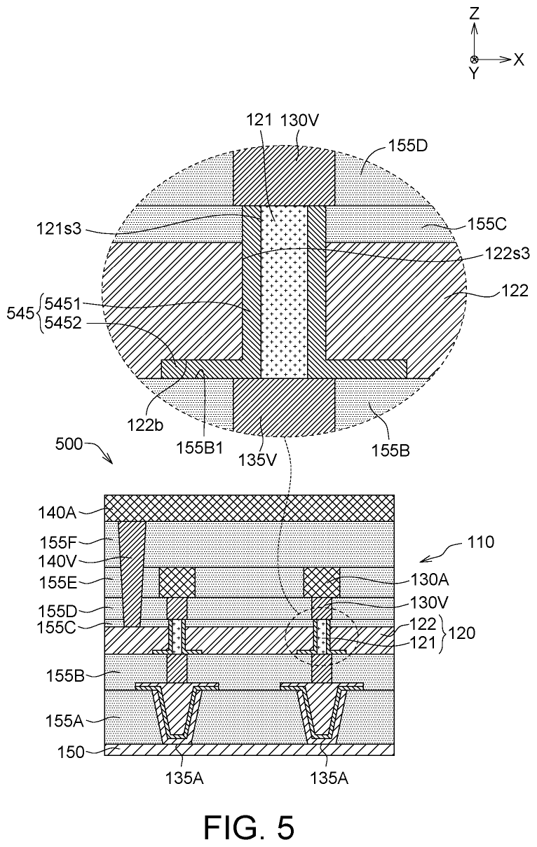

As illustrated in FIG. 5, FIG. 5 illustrates a schematic diagram of a cross-sectional view of a semiconductor device 500 according to another embodiment. The semiconductor device 500 includes the BEOL structure 110, at least one transistor 120, at least one bit line 130A, at least one bit line via 130V, at least one capacitor 135A, at least one capacitor via 135V, at least one word line 140A, at least one word line via 140V, at least one gate dielectric layer 545, the conductive layer 150 and at least one insulation layer (for example, including the first insulation layer 155A, the second insulation layer 155B, the third insulation layer 155C, the fourth insulation layer 155D, the fifth insulation layer 155E, a sixth insulation layer 155F, etc.). The bit line 130A, the bit line via 130V, the capacitor 135A, the capacitor via 135V, the word line 140A, the word line via 140V, the gate dielectric layer 545, the conductive layer 150 and the insulation layer are formed on/within the BEOL structure 110.

The semiconductor device 500 includes the features the same as or similar to that of the semiconductor device 100, and at least one difference is that the gate dielectric layer 545 of the semiconductor device 500 and the gate dielectric layer 545 of the semiconductor device 100 are different in structure. Furthermore, in the present embodiment, as illustrated in FIG. 5, each gate dielectric layer 545 includes a first portion 5451 and a second 5452, wherein the first portion 5451 is formed adjacent to the lateral surface 121s3 and formed between the lateral surface 121s3 of the active channel 121 and a lateral surface 122s3 of the metal gate 122. The second portion 5452 is formed between the end surface 122b of the metal gate 122 and the end surface 155B1 of the second insulation layer 155B. In the present embodiment, adjacent two gate dielectric layers 545 are separated by the metal gate 122.

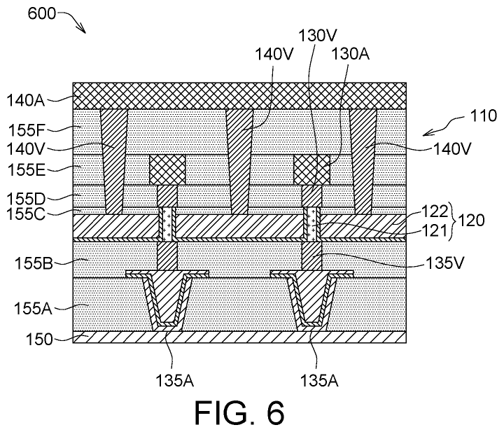

As illustrated in FIG. 6, FIG. 6 illustrates a schematic diagram of a cross-sectional view of a semiconductor device 600 according to another embodiment. The semiconductor device 600 includes the BEOL structure 110, at least one transistor 120, at least one bit line 130A, at least one bit line via 130V, at least one capacitor 135A, at least one capacitor via 135V, at least one word line 140A, a plurality of the word line vias 140V, at least one gate dielectric layer 145, the conductive layer 150 and at least one insulation layer (for example, including the first insulation layer 155A, the second insulation layer 155B, the third insulation layer 155C, the fourth insulation layer 155D, the fifth insulation layer 155E, a sixth insulation layer 155F, etc.). The bit line 130A, the bit line via 130V, the capacitor 135A, the capacitor via 135V, the word line 140A, the word line via 140V, the gate dielectric layer 145, the conductive layer 150 and the insulation layer are formed on/within the BEOL structure 110.

The semiconductor device 600 includes the features the same as or similar to that of the semiconductor device 100, and at least one difference is that a plurality of the word line vias 140V are connected the transistor 120. As a result, the word line vias 140V along each cell row may help reduce the word-line resistance and improve read/write speed of the DRAM.

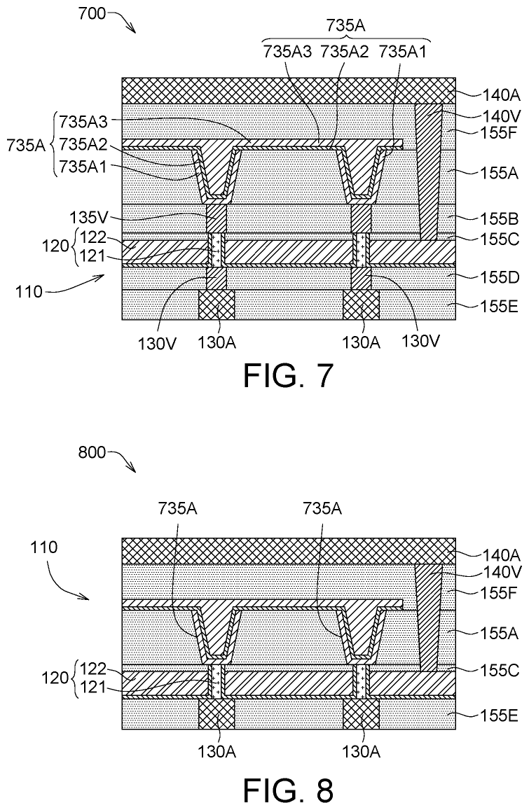

As illustrated in FIG. 7, FIG. 7 illustrates a schematic diagram of a cross-sectional view of a semiconductor device 700 according to another embodiment. The semiconductor device 700 includes the BEOL structure 110, at least one transistor 120, at least one bit line 130A, at least one bit line via 130V, at least one capacitor 735A, at least one capacitor via 135V, at least one word line 140A, a plurality of the word line vias 140V, at least one gate dielectric layer 145, the conductive layer 150 and at least one insulation layer (for example, including the first insulation layer 155A, the second insulation layer 155B, the third insulation layer 155C, the fourth insulation layer 155D, the fifth insulation layer 155E, a sixth insulation layer 155F, etc.). The bit line 130A, the bit line via 130V, the capacitor 735A, the capacitor via 135V, the word line 140A, the word line via 140V, the gate dielectric layer 145, the conductive layer 150 and the insulation layer are formed on/within the BEOL structure 110.

The semiconductor device 700 includes the features the same as or similar to that of the semiconductor device 100, and at least one difference is that the capacitors 735A are located above the transistor 120.

As illustrated in FIG. 7, each capacitor 735A includes a first electrode 735A1, a capacitor dielectric layer 735A2 and a second electrode 735A3, wherein the capacitor dielectric layer 735A2 is formed between the first electrode 735A1 and the second electrode 735A3. In the present embodiment, the second electrodes 735A3 of the two capacitors 735A are connected with each other. In addition, the sixth insulation layer 155F covers the capacitors 735A. Furthermore, the sixth insulation layer 155F covers the second electrodes 735A3 of the capacitors 735A. Each first electrode 735A1 of the capacitor 735A is connected with the corresponding capacitor via 135V. In an embodiment, at least two of the capacitors 735A may be directly or indirectly electrically connected with each other. In addition, the first electrode 735A1 and the second electrode 735A3 may be formed of a conductive material including metal, for example. The capacitor dielectric layer 735A2 may be formed of a high-k material, for example.

As illustrated in FIG. 7, the word line via 140V connects the word line 140A with the metal gate 122 through the sixth insulation layer 155F, the first insulation layer 155A, the second insulation layer 155B and the third insulation layer 155C.

As illustrated in FIG. 8, FIG. 8 illustrates a schematic diagram of a cross-sectional view of a semiconductor device 800 according to another embodiment. The semiconductor device 800 includes the BEOL structure 110, at least one transistor 120, at least one bit line 130A, at least one capacitor 735A, at least one word line 140A, a plurality of the word line vias 140V, at least one gate dielectric layer 145, the conductive layer 150 and at least one insulation layer (for example, including the first insulation layer 155A, the third insulation layer 155C, the fifth insulation layer 155E, a sixth insulation layer 155F, etc.). The bit line 130A, the capacitor 735A, the word line 140A, the word line via 140V, the gate dielectric layer 145, the conductive layer 150 and the insulation layer are formed on/within the BEOL structure 110.

The semiconductor device 800 includes the features the same as or similar to that of the semiconductor device 700, and difference is that the semiconductor device 800 may omit at least one of the bit line via 130V and the capacitor via 135V. In the present embodiment, the active channel 121 of the transistor 120 may directly connect the bit line 130A with the capacitor 735A. The word line via 140V connects the word line 140A with the metal gate 122 through the sixth insulation layer 155F, the first insulation layer 155A and the third insulation layer 155C.

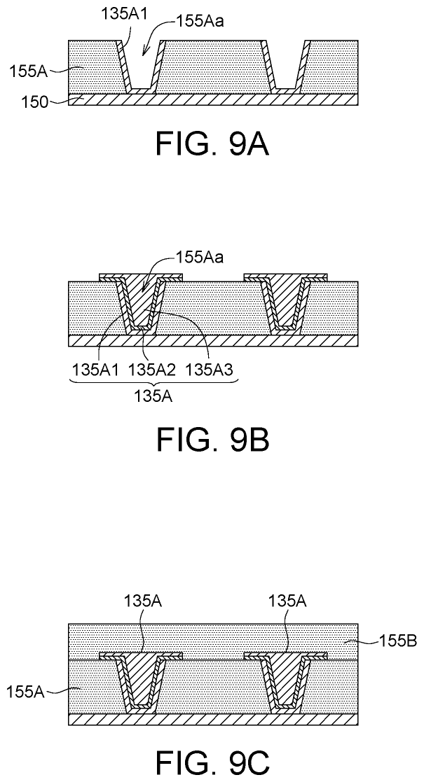

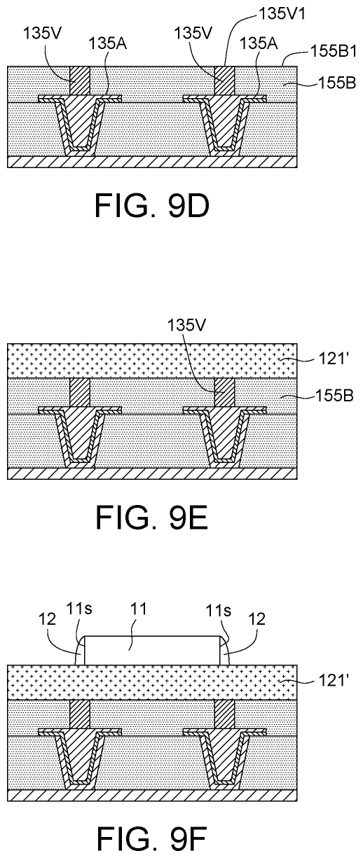

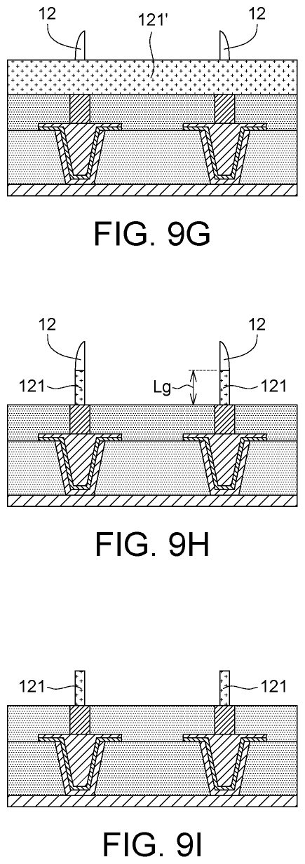

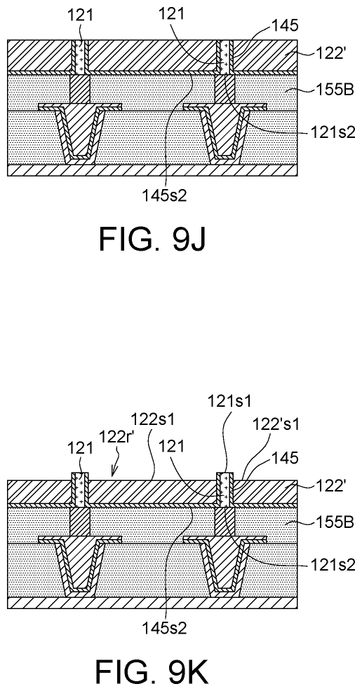

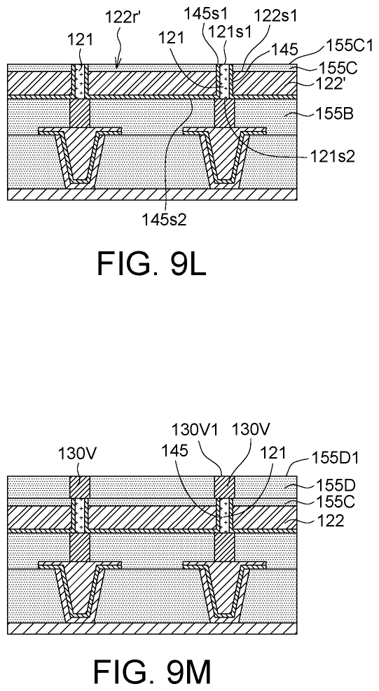

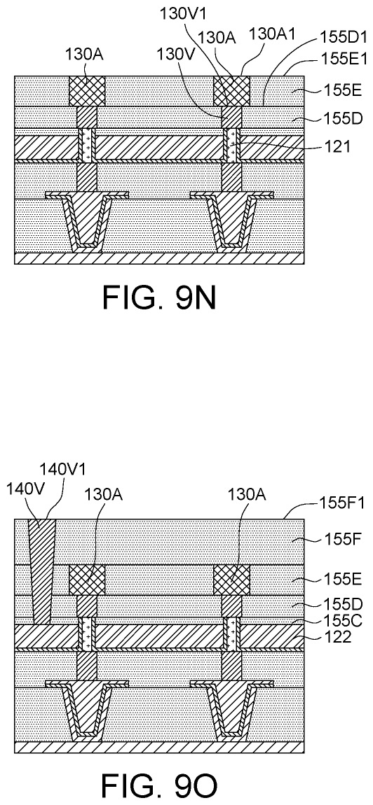

FIGS. 9A to 9O illustrate schematic diagrams of manufacturing processes of the semiconductor device 100 in FIG. 1A.

As illustrated in FIG. 9A, the first insulation layer 155A having at least one hole 155Aa is formed on the conductive layer 150 by using, for example, deposition, photolithography (at least including photoresist coating, exposure, development, etc.), etching, etc. Then, the first electrode 135A1 may be formed on a sidewall of the hole 155Aa and the conductive layer 150 exposed from the hole 155Aa by using, for example, deposition, etching back, etc.

As illustrated in FIG. 9B, the capacitor dielectric layer 135A2 formed on the first electrode 135A1 and the second electrode 135A3 formed on the capacitor dielectric layer 135A2 is formed by using, for example, deposition, photolithography, etching, etc. The first electrode 135A1, the capacitor dielectric layer 135A2 and the second electrode 135A3 form the capacitor 135A.

As illustrated in FIG. 9C, the second insulation layer 155B covering the capacitors 135A and the first insulation layer is formed by using, for example, deposition, etc.

As illustrated in FIG. 9D, the capacitor via 135V electrically connecting to the capacitor 135A may be formed within the second insulation layer 155B by using, for example, photolithography, etching, deposition, CMP (Chemical-Mechanical Planarization). After CMP, the capacitor via 135V forms an end surface 135V1 and the second insulation layer 155B forms the end surface 155B1, wherein the end surface 135V1 of the capacitor via 135V and the end surface 155B1 of the second insulation layer 155B are substantially aligned (for example, flushed) with each other, or substantially coplanar, for example.

As illustrated in FIG. 9E, the active channel material 121′ is formed to cover the second insulation layer 155B and the capacitor via 135V by using, for example, deposition, etc.

As illustrated in FIG. 9F, at least one dummy wire 11 formed on the active channel material 121′ by using, for example, deposition, photolithography, etc. Then, at least one spacer 12 is formed on a lateral surface 11s of the dummy wire 11 by using, for example, deposition, photolithography, etching, etc. In an embodiment, the dummy wire 11 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy wire 11 may be formed of silicon oxide non-conductive material). The dummy wire 11 may be deposited by physical vapor deposition (PVD), CVD, sputter deposition, or other techniques for depositing the selected material. The dummy wire 11 may be formed of other materials that have a high etching selectivity from the etching of isolation regions. In addition, the spacer 12 may be formed from a material including another of SiO, SiN, SiOC, SiON and SiOCN. In an embodiment, the dummy wire 11 may be formed of a material different from that of the spacer 12. For example, the dummy wire 11 is formed of, for example, silicon oxide, while the spacer 12 is formed of, for example, silicon nitrogen (SiN).

As illustrated in FIG. 9G, the dummy wire 11 is removed to expose the active channel material 121′ by using, for example, etching, etc.

As illustrated in FIG. 9H, a portion of the active channel material 121′ is removed to form, through the spacer 12, at least one active channel 121 by using, for example, etching, etc. In the present embodiment, the spacer 12 may serve as a hard mask for the formation of the active channel 121.

In the present embodiment, with the disposal spacer process, the channel region may be made very thin to have a better gate control. Thus, even if the channel length Lg of the active channel 121 is scaled down, short channel effect may still be suppressed. In addition, in the present embodiment, with the disposal spacer process, the gate of the access transistor may be either in double gate (DG) configuration (for example, the semiconductor devices 100, 300, 400, 500, 600, 700 and 800) or GAA configuration (for example, the semiconductor device 200) to provide a better gate control. Thus, even if the channel length Lg is scaled down, short channel effect may still be suppressed.

As illustrated in FIG. 9I, the spacers 12 may be removed by using, for example, etching, etc.

As illustrated in FIG. 9J, the gate dielectric layer 145 covering the second insulation layer 155B and the active channel 121 is formed by using, for example, deposition, etc. Then, the metal gate layer 122′ may be formed on the gate dielectric layer 145 by using, for example, deposition, etc. Then, the metal gate layer 122′, the gate dielectric layer 145 and the active channel 121 may be planarized by, for example, CMP.

As illustrated in FIG. 9K, a portion of the metal gate layer 122′ may be removed by using, for example, etching back. After etching, the metal gate layer 122′ is thinned, and the active channel 121 and the gate dielectric layer 145 protrude relative to the first conductive surface 122s1 of the metal gate layer 122′. The metal gate layer 122′ has a recessed portion 122r′ recessed relative to the first end surface 121s1 of the active channel 121.

As illustrated in FIG. 9L, the third insulation layer 155C in the recessed portion 122r′ is formed to cover the first conductive surface 122s1 of the metal gate layer 122′ by using, for example, deposition, etc. Then, the active channel 121, the third insulation layer 155C and the gate dielectric layer 145 may be planarized by using, for example, CMP. After CMP, the first end surface 121s of the active channel 121, an insulation 155C1 of the third insulation layer 155C and the first end surface 145s1 of the gate dielectric layer 145 are substantially aligned (for example, flushed) with each other or coplanar, for example. In addition, due to the CMP for the capacitor via 135V and the second insulation layer 155B in FIG. 9D, the second end surface 121s2 of the active channel 121 and the second end surface 145s2 of gate dielectric layer 145 are substantially aligned (for example, flushed) with each other or substantially coplanar, for example.

Then, the metal gate layer 122′ may be singulated to form the metal gate 122 as illustrated in FIGS. 1B and 1C. After singulation, at least gap G1 in FIG. 1B passing through a portion of the metal gate layer 122′, a portion of the gate dielectric layer 145 and a portion of the third insulation layer 155C in FIG. 9L is formed by using, for example, deposition, photolithography, etching, etc. The gaps G1 may define the region of the transistor.

As illustrated in FIG. 9M, the fourth insulation layer 155D covering the active channel 121, the metal gate 122 and the gate dielectric layer 145 is formed by using, for example, deposition, etc.

Then, as illustrated in FIG. 9M, the bit line via 130V electrically connected to the active channel 121 is formed in or within the fourth insulation layer 155D by using, for example, photolithography, etching, deposition, CMP, etc. After CMP, the bit line via 130V forms the end surface 130V1, and the fourth insulation layer 155D forms an end surface 155D1, wherein the end surface 130V1 of the bit line via 130V and the end surface 155D1 of the fourth insulation layer 155D are aligned (for example, flushed) with each other or substantially coplanar, for example.

As illustrated in FIG. 9N, the fifth insulation layer 155E covering the bit line via 130V and the fourth insulation layer 155D is formed by using, for example, deposition, etc.

Then, as illustrated in FIG. 9P, the bit line 130A electrically connected to the bit line via 130V is formed through the fifth insulation layer 155E by using, for example, photolithography, etching, deposition, CMP, etc. After CMP, the bit line 130A forms an end surface 130A1, and the fifth insulation layer 155E forms an end surface 155E1, wherein the end surface 130A1 of the bit line 130A and the end surface 155E1 of the fifth insulation layer 155E are substantially aligned (for example, flushed) with each other or substantially coplanar, for example.

As illustrated in FIG. 9O, the sixth insulation layer 155F covering the fifth insulation layer 155E and the bit line 130A is formed by using, for example, deposition, etc. Then, at least one word line via 140V passing through the sixth insulation layer 155F, the fifth insulation layer 155E, the fourth insulation layer 155D and the third insulation layer 155C is formed to be electrically connected to the metal gate 122 by using, for example, photolithography, etching, deposition, CMP, etc. After CMP, the word line via 140V forms an end surface 140V1, and the sixth insulation layer 155F forms an end surface 155F1, wherein the end surface 140V1 of the word line via 140V and the end surface 155F1 of the sixth insulation layer 155F are substantially aligned (for example, flushed) with each other or substantially coplanar, for example.

Then, at least one word line 140A (as illustrated in FIG. 1B) electrically connected to the word line via 140V is formed on the sixth insulation layer 155F to form the semiconductor device 100 in FIG. 1B by using, for example, deposition, photolithography, etching, etc.

The manufacturing method of one of the semiconductor devices 200, 300, 400, 500 and 600 may include the manufacturing processes similar to or the same as that of the semiconductor device 100, and it will not repeated here.

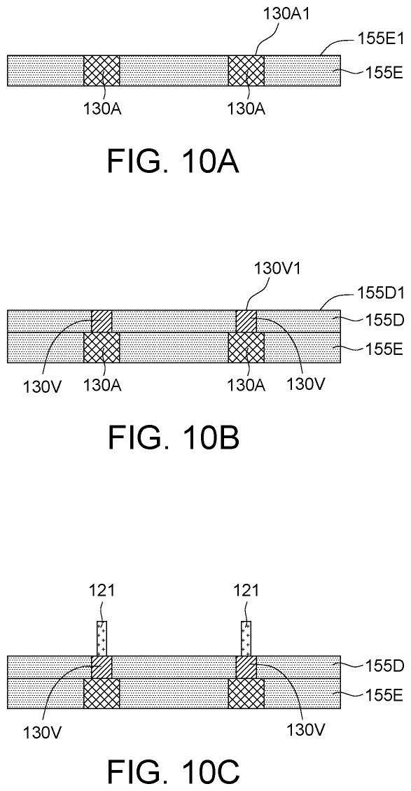

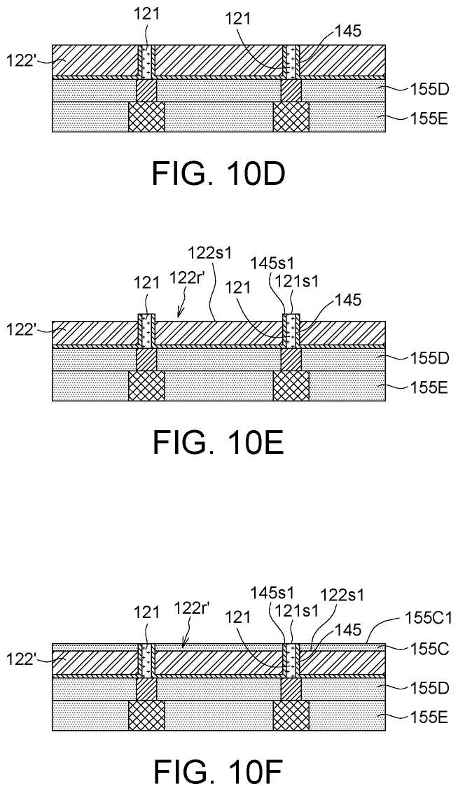

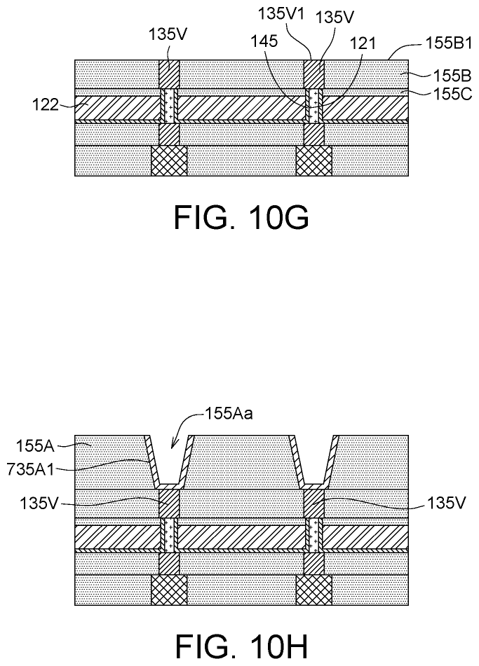

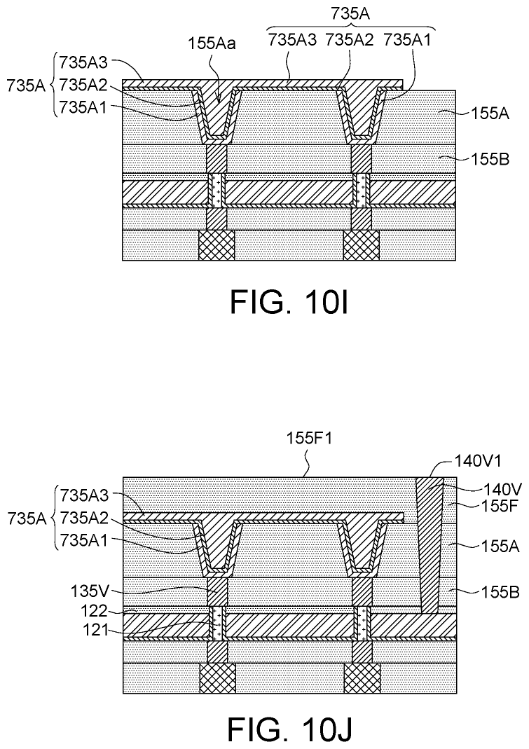

FIGS. 10A to 10J illustrate schematic diagrams of manufacturing processes of the semiconductor device 700 in FIG. 7.

As illustrated in FIG. 10A, the fifth insulation layer 155E is formed by using, for example, deposition, etc. Then, the bit line 130A is formed in or within the fifth insulation layer 155E by using, for example, photolithography, etching, deposition, CMP, etc. After CMP, the bit line 130A forms the end surface 130A1, and the fifth insulation layer 155E forms the end surface 155E1, wherein the end surface 130A1, of the bit line 130A and the end surface 155E1 of the fifth insulation layer 155E are substantially aligned (for example, flushed) with each other or substantially coplanar, for example.

As illustrated in FIG. 10B, the fourth insulation layer 155D covering the fifth insulation layer 155E and the bit line 130A is formed by using, for example, deposition, etc. Then, at least one bit line via 130V electrically connected to the bit line 130A is formed within the fourth insulation layer 155D by using, for example, photolithography, etching, deposition, CMP, etc. After CMP, the bit line via 130V forms the end surface 130V1, and the fourth insulation layer 155D forms an end surface 155D1, wherein the end surface 130V1 of the bit line via 130V and the end surface 155D1 of the fourth insulation layer 155D are substantially aligned (for example, flushed) with each other or substantially coplanar, for example.

As illustrated in FIG. 10C, at least one active channel 121 electrically connected to the bit line via 130V is formed by the processes similar to or the same as that of the semiconductor device 100 (for example, FIGS. 9E to 9I).

As illustrated in FIG. 10D, the gate dielectric layer 145 covering the fourth insulation layer 155D and the active channel 121 is formed by using, for example, deposition, etc. Then, the metal gate layer 122′ may be formed on the gate dielectric layer 145 by using, for example, deposition, etc. Then, the metal gate layer 122′, the gate dielectric layer 145 and the active channel 121 may be planarized by, for example, CMP.As illustrated in FIG. 10E, a portion of the metal gate layer 122′ may be removed by using, for example, etching back. After etching, the metal gate layer 122′ is thinned, and the active channel 121 and the gate dielectric layer 145 protrude relative to the first conductive surface 122s1 of the metal gate layer 122′. The metal gate layer 122′ has a recessed portion 122r′ recessed relative to the first end surface 121s1 of the active channel 121.

As illustrated in FIG. 10F, the third insulation layer 155C in the recessed portion 122r′ is formed to cover the first conductive surface 122s1 of the metal gate layer 122′ by using, for example, deposition, etc. Then, the active channel 121, the third insulation layer 155C and the gate dielectric layer 145 may be planarized by using, for example, CMP. After CMP, the first end surface 121s of the active channel 121, the insulation 155C1 of the third insulation layer 155C and the first end surface 145s1 of the gate dielectric layer 145 are substantially aligned (for example, flushed) with each other or substantially coplanar, for example.

Then, the metal gate layer 122′ may be singulated to form the metal gate 122 as illustrated in FIGS. 1B and 1C. After singulation, at least gap G1 in FIG. 1B passing through a portion of the metal gate layer 122′, a portion of the gate dielectric layer 145 and a portion of the third insulation layer 155C in FIG. 10F is formed by using, for example, deposition, photolithography, etching, etc. The gaps G1 may define the region of the transistor.

As illustrated in FIG. 10G, the second insulation layer 155B covering the active channel 121, the metal gate 122 and the gate dielectric layer 145 is formed by using, for example, deposition, etc.

Then, as illustrated in FIG. 10G, the capacitor via 135V electrically connected to the active channel 121 is formed in or within the second insulation layer 155B by using, for example, photolithography, etching, deposition, CMP, etc. After CMP, the capacitor via 135V forms the end surface 135V1, and the second insulation layer 155B forms the end surface 155B1, wherein the end surface 135V1 of the capacitor via 135V and the end surface 155B1 of the second insulation layer 155B are substantially aligned (for example, flushed) with each other or substantially coplanar, for example.

As illustrated in FIG. 10H, the first insulation layer 155A having at least one hole 155Aa is formed on the second insulation layer 155B by using, for example, deposition, photolithography, etching, etc. Then, the first electrode 735A1 may be formed on a sidewall of the hole 155Aa and the capacitor via 135V exposed from the hole 155Aa by using, for example, deposition, etching back, etc.

As illustrated in FIG. 10I, the capacitor dielectric layer 735A2 formed on the first electrode 735A1 and the second electrode 735A3 formed on the capacitor dielectric layer 735A2 are formed by using, for example, deposition, photolithography, etching, etc. The first electrode 735A1, the capacitor dielectric layer 735A2 and the second electrode 735A3 form the capacitor 735A. In the present embodiment, at least two of the capacitors 735A may be directly or indirectly electrically connected with each other. In another embodiment, at least two of the capacitors 735A may be separated from each other.

As illustrated in FIG. 10J, the sixth insulation layer 155F covering the first insulation layer 155A and the capacitor 735A is formed by using, for example, deposition, etc. Then, at least one word line via 140V passing through the sixth insulation layer 155F, the first insulation layer 155A and the second insulation layer 155B is formed to be electrically connected to the metal gate 122 by using, for example, photolithography, etching, deposition, CMP, etc. After CMP, the word line via 140V forms the end surface 140V1, and the sixth insulation layer 155F forms the end surface 155F1, wherein the end surface 140V1 of the word line via 140V and the end surface 155F1 of the sixth insulation layer 155F are substantially aligned (for example, flushed) with each other or substantially coplanar, for example.

Then, at least one word line 140A (as illustrated in FIG. 7) electrically connected to the word line via 140V is formed on the sixth insulation layer 155F to form the semiconductor device 700 in FIG. 7 by using, for example, deposition, photolithography, etching, etc.

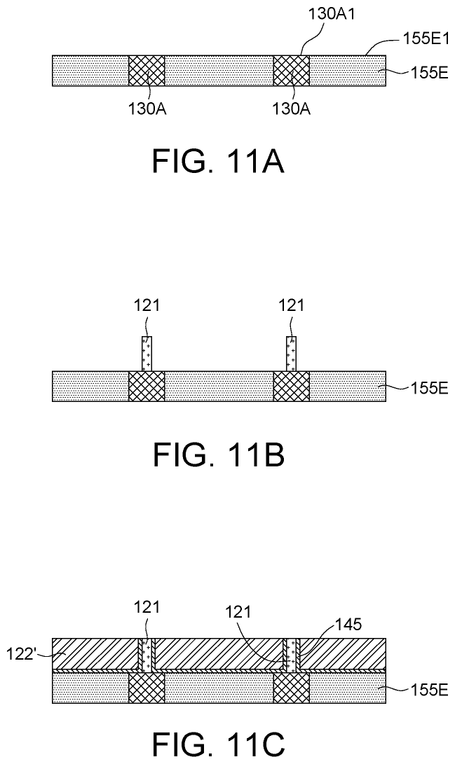

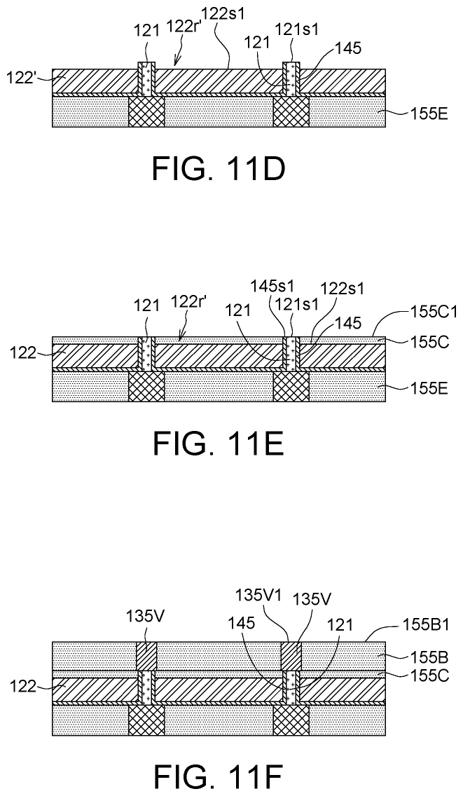

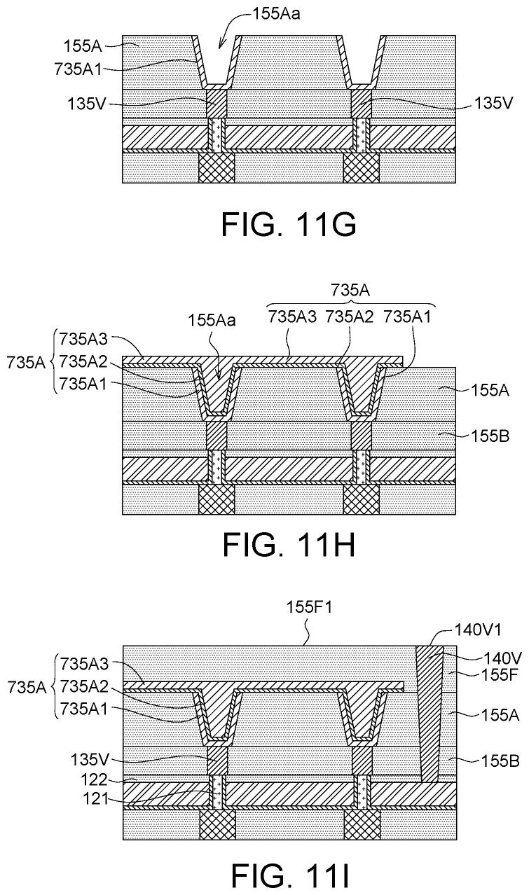

FIGS. 11A to 11I illustrate schematic diagrams of manufacturing processes of the semiconductor device 800 in FIG. 8.

As illustrated in FIG. 11A, the fifth insulation layer 155E is formed by using, for example, deposition, etc. Then, the bit line 130A is formed in or within the fifth insulation layer 155E by using, for example, photolithography, etching, deposition, CMP, etc. After CMP, the bit line 130A forms the end surface 130A1, and the fifth insulation layer 155E forms the end surface 155E1, wherein the end surface 130A1, of the bit line 130A and the end surface 155E1 of the fifth insulation layer 155E are substantially aligned (for example, flushed) with each other or substantially coplanar, for example.

As illustrated in FIG. 11B, at least one active channel 121 electrically connected to the bit line 130A is formed by the processes similar to or the same as that of the semiconductor device 100 (for example, FIGS. 9E to 9I).

As illustrated in FIG. 11C, the gate dielectric layer 145 covering the fifth insulation layer 155E and the active channel 121 is formed by using, for example, deposition, etc. Then, the metal gate layer 122′ may be formed on the gate dielectric layer 145 by using, for example, deposition, etc. Then, the metal gate layer 122′, the gate dielectric layer 145 and the active channel 121 may be planarized by, for example, CMP.

As illustrated in FIG. 11D, a portion of the metal gate layer 122′ may be removed by using, for example, etching back. After etching, the metal gate layer 122′ is thinned, and the active channel 121 and the gate dielectric layer 145 protrude relative to the first conductive surface 122s1 of the metal gate layer 122′. The metal gate layer 122′ has a recessed portion 122r′ recessed relative to the first end surface 121s1 of the active channel 121.

As illustrated in FIG. 11E, the third insulation layer 155C in the recessed portion 122r′ is formed to cover the first conductive surface 122s1 of the metal gate layer 122′ by using, for example, deposition, etc. Then, the active channel 121, the third insulation layer 155C and the gate dielectric layer 145 may be planarized by using, for example, CMP. After CMP, the first end surface 121s of the active channel 121, the insulation 155C1 of the third insulation layer 155C and the first end surface 145s1 of the gate dielectric layer 145 are substantially aligned (for example, flushed) with each other or substantially coplanar, for example.

Then, the metal gate layer 122′ may be singulated to form the metal gate 122 as illustrated in FIGS. 1B and 1C. After singulation, at least gap G1 in FIG. 1B passing through a portion of the metal gate layer 122′, a portion of the gate dielectric layer 145 and a portion of the third insulation layer 155C in FIG. 10F is formed by using, for example, deposition, photolithography, etching, etc. The gaps G1 may define the region of the transistor.

As illustrated in FIG. 11F, the second insulation layer 155B covering the active channel 121, the metal gate 122 and the gate dielectric layer 145 is formed by using, for example, deposition, etc.

Then, as illustrated in FIG. 11G, the capacitor via 135V electrically connected to the active channel 121 is formed in or within the second insulation layer 155B by using, for example, photolithography, etching, deposition, CMP, etc. After CMP, the capacitor via 135V forms the end surface 135V1, and the second insulation layer 155B forms the end surface 155B1, wherein the end surface 135V1 of the capacitor via 135V and the end surface 155B1 of the second insulation layer 155B are substantially aligned (for example, flushed) with each other or substantially coplanar, for example.

As illustrated in FIG. 11G, the first insulation layer 155A having at least one hole 155Aa is formed on the second insulation layer 155B by using, for example, deposition, photolithography, etching, etc. Then, the first electrode 735A1 may be formed on a sidewall of the hole 155Aa and the capacitor via 135V exposed from the hole 155Aa by using, for example, deposition, etching back, etc.

As illustrated in FIG. 11H, the capacitor dielectric layer 735A2 formed on the first electrode 735A1 and the second electrode 735A3 formed on the capacitor dielectric layer 735A2 are formed by using, for example, deposition, photolithography, etching, etc. The first electrode 735A1, the capacitor dielectric layer 735A2 and the second electrode 735A3 form the capacitor 735A. In the present embodiment, at least two of the capacitors 735A may be directly or indirectly electrically connected with each other. In another embodiment, at least two of the capacitors 735A may be separated from each other.

As illustrated in FIG. 11I, the sixth insulation layer 155F covering the first insulation layer 155A and the capacitor 735A is formed by using, for example, deposition, etc. Then, at least one word line via 140V passing through the sixth insulation layer 155F, the first insulation layer 155A and the second insulation layer 155B is formed to be electrically connected to the metal gate 122 by using, for example, photolithography, etching, deposition, CMP, etc. After CMP, the word line via 140V forms the end surface 140V1, and the sixth insulation layer 155F forms the end surface 155F1, wherein the end surface 140V1 of the word line via 140V and the end surface 155F1 of the sixth insulation layer 155F are substantially aligned (for example, flushed) with each other or substantially coplanar, for example.

Then, at least one word line 140A (as illustrated in FIG. 8) electrically connected to the word line via 140V is formed on the sixth insulation layer 155F to form the semiconductor device 800 in FIG. 8 by using, for example, deposition, photolithography, etching, etc.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device and a manufacturing method thereof. The semiconductor device at least includes a vertical active channel, and it may help to reduce cell area and results in high density DRAM, for example.

Example embodiment 1: a semiconductor device includes a BEOL structure and a transistor formed on the BEOL structure. The transistor is disposed on the BEOL structure and includes an active channel and a metal gate. The active channel has a first end surface and a lateral surface. The metal gate has a first conductive surface and disposed adjacent to the lateral surface of the active channel. The first end surface of the active channel protrudes relative to the first conductive surface of the metal gate.

Example embodiment 2 based on Example embodiment 1: the active channel further has a second end surface opposite to the first end surface, the metal gate further has a second conductive surface opposite to the first conductive surface, and the second end surface of the active channel and the second conductive surface of the metal gate are flushed with each other.

Example embodiment 3 based on Example embodiment 1: the active channel further has a second end surface opposite to the first end surface, and the manufacturing device further includes a bit line via and a capacitor via, wherein the bit line via is connected with the first end surface, and the capacitor via connected with the second end surface.

Example embodiment 4 based on Example embodiment 3: the bit line via, the active channel and the capacitor via are stacked in a thickness direction of the semiconductor device.

Example embodiment 5 based on Example embodiment 1: the active channel and the metal gate overlap in an extension direction perpendicular to a thickness direction of the semiconductor device.

Example embodiment 6 based on Example embodiment 1: the active channel has a lateral surface; the semiconductor device further includes a gate dielectric layer disposed between the lateral surface of the active channel and the metal gate.

Example embodiment 7 based on Example embodiment 6: the semiconductor device further includes an insulation layer, wherein the gate dielectric layer is disposed between insulation layer and the metal gate, and the gate dielectric layer includes a first portion and a second portion. The first portion is disposed between the lateral surface of the active channel and a lateral surface of the metal gate, and the second portion is disposed between an end surface of the insulation layer and an end surface of metal gate.

Example embodiment 8 based on Example embodiment 1: the semiconductor device further includes an insulation layer, a word line and a word line via. The word line is disposed on the insulation layer. The word line via is disposed within the insulation layer and connects the word line with the metal gate.

Example embodiment 9 based on Example embodiment 1: the semiconductor device further includes a word line and a capacitor. The word line is electrically connected with the metal gate. The capacitor is electrically connected with the active channel and located between the word line and the metal gate.

Example embodiment 10 based on Example embodiment 1: the semiconductor device further includes a capacitor via connected with the active channel. The active channel entirely overlaps the capacitor via in the thickness direction.

Example embodiment 11: the semiconductor device includes a BEOL structure, a transistor and a capacitor. The transistor is disposed on the BEOL structure and includes an active channel and a metal gate. The capacitor is disposed within the BEOL structure. The active channel has a lateral surface and extends a thickness direction of the semiconductor device. The metal gate is disposed adjacent to the lateral surface of the active channel.

Example embodiment 12 based on Example embodiment 11: the active channel further has a first end surface and a second end surface opposite to the first end surface, the metal gate further has a first conductive surface and a second conductive surface opposite to the first conductive surface, the first end surface of the active channel protrudes relative to the first conductive surface of the metal gate, and the second end surface of the active channel and the second conductive surface of the metal gate are flushed with each other.

Example embodiment 13 based on Example embodiment 11: the active channel further has a first end surface and a second end surface opposite to the first end surface, and the manufacturing device further includes a bit line via and a capacitor via. The bit line via is connected with the first end surface. The capacitor via is connected with the second end surface.

Example embodiment 14 based on Example embodiment 13: the bit line via, the active channel and the capacitor via are stacked in the thickness direction of the semiconductor device.

Example embodiment 15 based on Example embodiment 11: the semiconductor device further includes a gate dielectric layer disposed between the lateral surface of the active channel and the metal gate.

Example embodiment 16 based on Example embodiment 15: the semiconductor device further includes an insulation layer, wherein the gate dielectric layer is disposed between insulation layer and the metal gate. The gate dielectric layer includes a first portion and a second portion. The first portion is disposed between the lateral surface of the active channel and a lateral surface of the metal gate. The second portion is disposed between an end surface of the insulation layer and an end surface of metal gate.

Example embodiment 17 based on Example embodiment 11: the semiconductor device further includes an insulation layer, a word line and word line via. The word line is disposed on the insulation layer. The word line via is disposed within the insulation layer and connects the word line with the metal gate.

Example embodiment 18 based on Example embodiment 11: the semiconductor device further includes a word line and a capacitor. The word line is electrically connected with the metal gate. The capacitor is electrically connected with the active channel and located between the word line and the metal gate.

Example embodiment 19: a manufacturing method for a semiconductor device includes the following steps: forming a BEOL structure; and forming a transistor on the BEOL structure, including: forming an active channel material; forming a dummy wire on the active channel material; forming a spacer on a lateral surface of the dummy wire; removing the dummy wire to expose the active channel material; removing a portion of the active channel material, through the spacer, to form an active channel; removing the spacer; forming a metal gate to cover the active channel; and planarizing the metal gate and the active channel, wherein the active channel has a first end surface, the metal gate has a first conductive surface, and the first end surface of the active channel protrudes relative to the first conductive surface of the metal gate.

Example embodiment 20 based on Example embodiment 19: before forming the active channel material, the manufacturing method further include: forming a capacitor via. In forming the active channel material, the active channel material is electrically connected with the capacitor via. After planarizing the metal gate and the active channel, the manufacturing method further includes: forming a bit line via, wherein the bit line via, is electrically connected with the active channel, and the bit line via, the active channel and the capacitor via are stacked in a thickness direction of the semiconductor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a Back End of Line (BEOL) structure;
a transistor on the BEOL structure, comprising:
an active channel having a first end surface and a lateral surface; and
a metal gate having a first conductive surface and disposed adjacent to the lateral surface of the active channel;
wherein the first end surface of the active channel protrudes relative to the first conductive surface of the metal gate.

2. The semiconductor device as claimed in claim 1, wherein the active channel further has a second end surface opposite to the first end surface, the metal gate further has a second conductive surface opposite to the first conductive surface, and the second end surface of the active channel and the second conductive surface of the metal gate are flushed with each other.

3. The semiconductor device as claimed in claim 1, wherein the active channel further has a second end surface opposite to the first end surface, and the manufacturing device further comprises:
a bit line via connected with the first end surface; and
a capacitor via connected with the second end surface.

4. The semiconductor device as claimed in claim 3, wherein the bit line via, the active channel and the capacitor via are stacked in a thickness direction of the semiconductor device.

5. The semiconductor device as claimed in claim 1, wherein the active channel and the metal gate overlap in an extension direction perpendicular to a thickness direction of the semiconductor device.

6. The semiconductor device as claimed in claim 1, wherein the active channel has a lateral surface; the semiconductor device further comprises:
a gate dielectric layer disposed between the lateral surface of the active channel and the metal gate.

7. The semiconductor device as claimed in claim 6, further comprising:
an insulation layer, wherein the gate dielectric layer is disposed between insulation layer and the metal gate;
wherein the gate dielectric layer comprises:
a first portion disposed between the lateral surface of the active channel and a lateral surface of the metal gate; and
a second portion disposed between an end surface of the insulation layer and an end surface of metal gate.

8. The semiconductor device as claimed in claim 1, further comprising:
an insulation layer;
a word line disposed on the insulation layer; and
a word line via disposed within the insulation layer and connecting the word line with the metal gate.

9. The semiconductor device as claimed in claim 1, further comprises:
a word line electrically connected with the metal gate; and
a capacitor electrically connected with the active channel and located between the word line and the metal gate.

10. The semiconductor device as claimed in claim 1, further comprising:
a capacitor via connected with the active channel;
wherein the active channel entirely overlaps the capacitor via in the thickness direction.

11. A semiconductor device, comprising:
a BEOL structure;
a transistor on the BEOL structure, comprising:
an active channel having a lateral surface and extending a thickness direction of the semiconductor device; and
a metal gate adjacent to the lateral surface of the active channel;
a capacitor within the BEOL structure.

12. The semiconductor device as claimed in claim 11, wherein the active channel further has a first end surface and a second end surface opposite to the first end surface, the metal gate further has a first conductive surface and a second conductive surface opposite to the first conductive surface, the first end surface of the active channel protrudes relative to the first conductive surface of the metal gate, and the second end surface of the active channel and the second conductive surface of the metal gate are flushed with each other.

13. The semiconductor device as claimed in claim 11, wherein the active channel further has a first end surface and a second end surface opposite to the first end surface, and the manufacturing device further comprises:
a bit line via connected with the first end surface; and
a capacitor via connected with the second end surface.

14. The semiconductor device as claimed in claim 13, wherein the bit line via, the active channel and the capacitor via are stacked in the thickness direction of the semiconductor device.

15. The semiconductor device as claimed in claim 11, further comprises:
a gate dielectric layer disposed between the lateral surface of the active channel and the metal gate.

16. The semiconductor device as claimed in claim 15, further comprising:
an insulation layer, wherein the gate dielectric layer is disposed between insulation layer and the metal gate;
wherein the gate dielectric layer comprises:
a first portion disposed between the lateral surface of the active channel and a lateral surface of the metal gate; and
a second portion disposed between an end surface of the insulation layer and an end surface of metal gate.

17. The semiconductor device as claimed in claim 11, further comprising:
an insulation layer;
a word line disposed on the insulation layer; and
a word line via disposed within the insulation layer and connecting the word line with the metal gate.

18. The semiconductor device as claimed in claim 11, further comprises:
a word line electrically connected with the metal gate; and
a capacitor electrically connected with the active channel and located between the word line and the metal gate.

19. A manufacturing method for a semiconductor device, comprising:
forming a BEOL structure; and
forming a transistor on the BEOL structure, comprising:
forming an active channel material;
forming a dummy wire on the active channel material;
forming a spacer on a lateral surface of the dummy wire;
removing the dummy wire to expose the active channel material;
removing a portion of the active channel material, through the spacer, to form an active channel;
removing the spacer;
forming a metal gate to cover the active channel, wherein the metal gate is disposed adjacent to a lateral surface of the active channel; and
planarizing the metal gate and the active channel, wherein the active channel has a first end surface, the metal gate has a first conductive surface, and the first end surface of the active channel protrudes relative to the first conductive surface of the metal gate.

20. The manufacturing method as claimed in claim 19, wherein before forming the active channel material, the manufacturing method further comprises:
forming a capacitor via;
wherein in forming the active channel material, the active channel material is electrically connected with the capacitor via;
wherein after planarizing the metal gate and the active channel, the manufacturing method further comprises:
forming a bit line via, wherein the bit line via, is electrically connected with the active channel, and the bit line via, the active channel and the capacitor via are stacked in a thickness direction of the semiconductor device.
